(19) United States
(12) Patent Application Publication
(10) Pub. No.: US 2008/0242078 A1
(43) Pub. Date: Oct. 2, 2008

(54) PROCESS OF FILLING DEEP VIAS FOR 3-D INTEGRATION OF SUBSTRATES

(75) Inventors: Hessel Sprey, Kessel-Lo (BE); Hyung-Sang Park, Seoul (KR)

Correspondence Address: Knobbe, Martens, Olson & Bear LLP, 2040 Main Street, 14th Floor, Irvine, CA, 92614, US

(73) Assignee: ASM NUTOOL, INC., PHOENIX, AZ (US)

(21) Appl. No.: 11/694,686

(22) Filed: Mar. 30, 2007

(51) Int. Cl. H01L 21/3205

(52) U.S. Cl. 438/643; 257/E21.294

(57) ABSTRACT

A method for filling defect-free conductive material in deep vias or cavities in semiconductor wafers in 3-D integration structures is provided. The process may be performed in at least two steps for depositing the conductive material, including a first deposition step that partially fills the cavity with the conductive material and forms a conformal layer, which may also reduce the depth and width of the cavity, and a second deposition step that completely fills the same conductive material into the space defined by the conformal layer.

### FIELD

The present invention generally relates to semiconductor integrated circuit (IC) processing technologies and, more particularly, to a process for filling deep vias.

### BACKGROUND

Integrated circuits (ICs) include many devices and circuit members that are formed on a single semiconductor wafer. The current trends in IC technology are towards faster and more powerful circuits. However, as more complex ICs, such as microprocessors having high operating frequency ranges, are manufactured, various speed related problems are becoming increasingly challenging. This is especially true when ICs having different functions are used to create electronic systems, for example computing systems including processor and memory ICs, where different ICs are electrically connected by a global interconnect network. However, as the global interconnects become longer and more numerous in the electronic systems, RC delay and power consumption as well as low system performance are becoming limiting factors.

One proposed solution to this problem is three dimensional (3-D) integration or 3-D IC packaging technology, where 3-D integration refers to the vertical stacking of multiple dies including ICs within a package. In 3-D integration technology, multiple wafers or dies are electrically connected using vertical interconnects formed in 3-D vias, which may have depths as well as widths or diameters as large as about 100 microns or greater. 3-D vias extend through one or more of the wafers or dies and are aligned when the wafers or dies are stacked to provide electrical communication among the ICs in the stacked wafers or dies. 3-D integration may result in reductions of size and weight of the IC package, reduction in power consumption, and increase in performance and reliability.

In general, to fabricate the 3-D interconnects, initially deep vias are formed in the wafers, which are subsequently filled with a conductive material, typically a metal such as copper for its low electrical resistivity and electromigration characteristics. Electroplating is one of the proposed methods for filling deep vias. In copper electroplating, copper ions in a copper electrolyte are chemically reduced and deposited on a conductive surface of a wafer while an external electrical current is applied to the conductive surface. Electroplating is a process that is well-understood and has been used to fabricate copper interconnect structures in semiconductor substrates for a considerable time. Copper interconnects are metal lines that are formed in the cavities or features formed in the semiconductor substrates, which can provide the electrical connections between the various electronic elements of an IC. An electroplating process generally involves depositing a conductive liner on a substrate surface and the interior of the features prior to electroplating. The conductive liner generally includes two material layers, namely a barrier layer and a seed layer. A barrier layer formed of, for example, Ta or TaN (approximately 50-200 Åthick) is initially deposited on the substrate, which may be a dielectric or semiconductor, to improve adhesion of the electroplated copper to the substrate while also preventing copper from diffusing into the substrate. Diffusion of electroplated conductive materials into the substrate material may cause short-circuits among the neighboring devices and result in device failure. Because conventional barrier layer materials often do not provide a sufficiently conductive surface to apply a plating current, a thin copper layer (approximately 50-1000 Åthick), or so-called seed layer, is often deposited on the barrier layer to provide effective electroplating. After the electroplating process, the excess copper on the surface, along with surface portions of the barrier layer, is removed from the surface using a planarization process, such as chemical mechanical polishing (CMP).

The yield of an electroplating process greatly depends on the thickness uniformity and conformality of the conductive liner. The barrier layer and the seed layer should be continuous and conformal. Formation of such a continuous conductive liner is particularly difficult when this layer is designed to cover the surface of a deep feature having an aspect ratio (depth of the feature/width of the feature) of greater than about 3. Although currently the preferred method of deposition of a barrier and a seed layers is physical vapor deposition (PVD), with plasma sputtering being preferred, application of PVD to fill deep vias is expensive and the resulting layers are far from conformal. For example, for the barrier layer, non-conformal coverage at the bottom of the deep via and on the side walls might permit the diffusion of copper atoms into the substrate and may form voids during electroplating. Conversely, if the deposition on the surface of the substrate is excessive, the subsequent barrier layer planarization step can be costly. As noted above, application of PVD to form a seed layer typically results in non-conformal deposition in deep vias such that the seed layer coating is often very thin or discontinuous at the side walls and the bottom of the via. Such inadequate seed layer coverage acts then as a poor nucleating surface for the subsequent electrodeposition of copper, causing problems, such as voids in the copper deposit. Such voids act as breaks in the conductive line preventing current flow. If the seed layer is too thick on the surface of the substrate, the top opening of the deep via may prematurely close off, preventing plating electrolyte flow, which can also result in voids. Such problems are further aggravated as the vias become deeper and narrower.

Conventional electroplating techniques, such as those briefly exemplified above, have shortcomings for meeting the present and future requirements of 3-D integration. Therefore, to this end, there is a need for alternative methods to allow deposition of conductors, such as copper, into deep vias without causing defects in the deposited conductor.

### SUMMARY

In accordance with an embodiment, a method is provided for filling a deep feature formed in a surface of a wafer with a conductor. The deep feature has a depth of at least about 10 microns. A conductive film is formed, the conductive film coating the deep feature and extending over the surface of the wafer. A first layer is deposited over the conductive film using a gas phase deposition process. The first layer comprises the conductor and partially fills the deep feature. A second layer comprising the conductor is formed over the first layer, using an electrochemical deposition process. The second layer completely fills the deep feature.

In accordance with another embodiment, a method is provided for filling features formed in an upper surface of a wafer with a conductor. A barrier layer is formed. The barrier layer coats interior surfaces of the features and extends over the upper surface of the wafer. The feature has a depth of at least about 10 microns. A seed layer is formed over the barrier layer. A first layer is deposited over the seed layer using a gas phase deposition process. The first layer comprises the conductor and partially fills the features and extends over the upper surface of the wafer. Using an electrochemical deposition process, a second layer is formed over the first layer. The second layer comprises the conductor and completely fills the features.

### BRIEF DESCRIPTION OF THE DRAWINGS

Exemplary embodiments of the methods and systems disclosed herein are illustrated in the accompanying drawings, which are for illustrative purposes only. The drawings comprise the following figures, in which like numerals indicate like parts.

FIG. 1A is a schematic illustration of a deep via coated with an ALD barrier layer followed with a MOCVD copper layer in accordance with an embodiment;

FIG. 1B is a schematic illustration of the deep via shown in FIG. 1A, which is filled with copper using ECD or ECMD;

FIG. 1C is a schematic illustration of the deep via shown in FIG. 1B, which is planarized using CMP or ECMP;

FIG. 2A is a schematic illustration of a deep via coated with a barrier layer and a copper seed layer followed with MOCVD copper layer in accordance with an embodiment;

FIG. 2B is a schematic illustration of the deep via shown in FIG. 2A, which is filled with copper using ECD or ECMD; and

FIG. 2C is a schematic illustration of the deep via shown in FIG. 2B, which is planarized using CMP or ECMP.

### DETAILED DESCRIPTION OF THE PREFERRED EMBODIMENTS

The embodiments described herein provide methods to deposit conductors in vias formed on semiconductor wafers. Furthermore, these embodiments provide an electrochemical deposition process for defect-free filling of features or cavities having large width and depth in, for example, 3-D integration structures. A process described herein electrofills a conductive material into such deep features having an aspect ratio of greater than about 2, preferably greater than 5, and typically in the range of 5-15. The process may be performed in at least three steps, including: a first step which coats a deep feature with a layer; a second step including a gas phase deposition process that partially fills the deep feature with a conductor and forms a continuous conformal layer, which may also reduce the depth and width of the deep feature; and a third step including an electrodeposition process that completely fills the deep feature by filling space defined by the conformal layer with the same conductor. After electrofilling conductive material into the deep feature or via to form a 3-D interconnect or a 3-D conductive plug for 3-D integration, a back end metallization process may be performed within the wafer to connect IC circuits to the plugs. After the back end metallization process, the wafer may be connected to other chips or wafers by grinding away the backside of the wafer until the conductive plug is exposed from the backside. It will be understood that the conductive plug can be used as a 3-D vertical interconnect to connect the chip or wafer to other chips or wafers for 3-D integration. The skilled artisan will appreciate that the sequence of steps can differ in different 3-D integration schemes.

According to a preferred embodiment, the first deposition step may be a gas phase deposition process, such as metallorganic chemical vapor deposition (MOCVD) and the second deposition step may be an electrodeposition step, such as electrochemical deposition (ECD), which fills the conductor preferably in a bottom-up fashion. MOCVD is a well-known chemical vapor deposition (CVD) process that uses metallorganic compounds as source materials, because metallorganic compounds thermally decompose at temperatures lower than other metal containing compounds. In a copper MOCVD process of an embodiment, complex organic copper gas molecules are passed over a heated substrate having the features. The heat breaks up the molecules and deposits the copper atoms on the surface of the substrate and into the interior of the features conformally. By varying the composition of the copper containing gas, the properties of the depositing MOCVD copper layer can be varied at an atomic scale. It will be understood that the MOCVD copper layer is typically less pure and has higher resistivity than a copper layer deposited by PVD due, inter alia, to carbon contamination.

The first gas-phase deposition step may be performed using a catalyst that promotes bottom-up filling during the second electrochemical deposition. In this example, the conductor that is deposited in both process steps may be copper or a copper alloy or another lower resistivity material. Before the first deposition step, the via and the surface of the wafer may be lined with a conductive layer, such as a barrier layer that is deposited, preferably using an atomic layer deposition (ALD) process, which can give near perfect conformality. Alternatively, the conductive layer may include a barrier layer and a seed layer combination. In this case, the barrier layer and the seed layer may be formed using ALD or other methods, such as physical vapor deposition (PVD) or chemical vapor deposition (CVD).

Embodiments are described below in the context of specific exemplary embodiments for copper deposition, although it is possible to deposit other low resistivity materials using the same principles. The method eliminates many of the problems associated with conventional electroplating techniques used in filling deep vias for 3-D integration or high aspect ratio vias used in interlevel interconnects. Use of an ALD barrier layer in conjunction with MOCVD copper layer allows for defect-free conductor filling of such deep features.

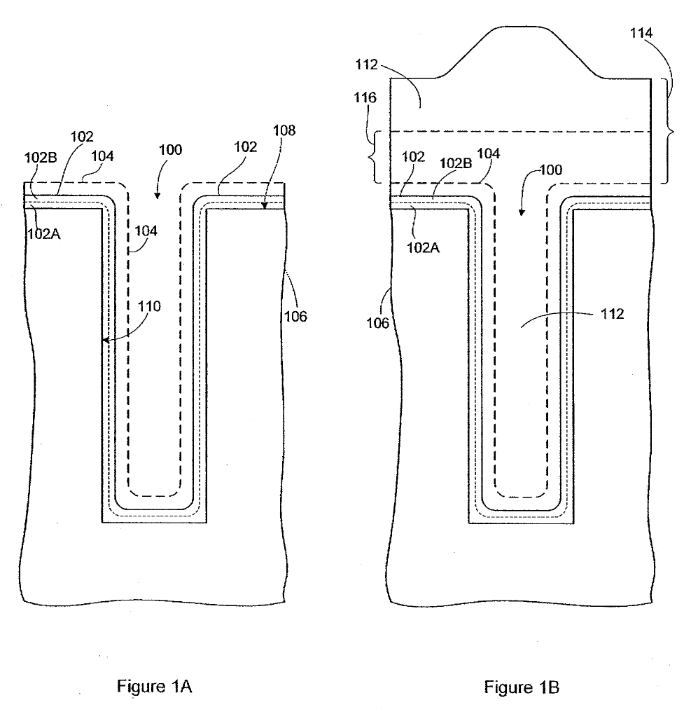

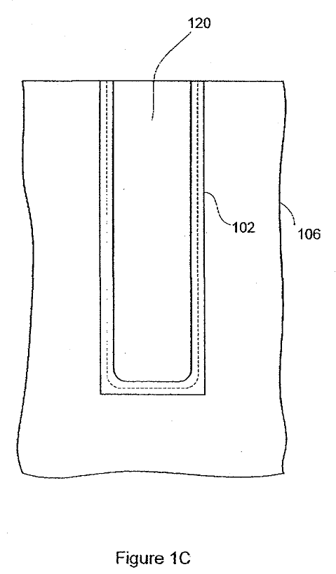

In a first embodiment, FIG. 1A shows an exemplary via 100, which is coated with a barrier layer 102 and a first conductive layer 104. The exemplary via 100 is formed in a substrate 106, which may be a portion of a semiconductor wafer (e.g., silicon wafer) or a dielectric layer. The barrier layer 102 is a conformal layer having a substantially uniform thickness and coats a top surface 108 of the substrate 106 as well as an interior surface 110 of the via 100. In this embodiment, the via 100 may be shaped as a round or rectangular hole (as viewed top down), which extends as a cylindrical or rectangular hole into the wafer. The walls of such holes are substantially perpendicular to the wafer surface It will be understood that the via may have an alternative shape. The walls of the via may be straight (as shown in the figures) or may be tapered at the bottom. It will be understood that the via 100 may have a width or diameter in the range of about 5 to 100 μm, and a depth in the range of about 10 to 250 μm. The via 100, in certain embodiments, has a diameter or width in the range of 5 to 15 μm, and more preferably about 10 μm. The depth of the via 100 is preferably in the range of 20 to 50 μm, and more preferably about 30 μm. It will be understood that, in other embodiments, the width or diameter of the via 100 may be in the range of about 50 to 100 μm, and the depth may be in the range of about 50-250 μm. In one embodiment, the depth is about 35 μm; in other embodiments, the depth may be 50 μm or higher. Greater depths result in less backside grinding. The aspect ratio of the via 100 is preferably between about 1 to 15, and more preferably between about 2 to 5.

The barrier layer 102 is deposited, preferably using an ALD process, to a thickness in the range of about 1 to 10 nanometers (nm). A process temperature of less than 400° C. is preferably used during the ALD process. The barrier layer 102 may be directly deposited onto the silicon substrate 106 or onto a dielectric layer, such as SiO₂ (not shown), which may be coated before the deposition of the barrier layer 102. Exemplary ALD deposited barrier layer materials may comprise Ru, WNC, WN, WC, TiN, TaN, TaCN, TaC, Co, CoWP, or Ni, or any possible combinations of these materials. Ru, Ni, and Co typically have a crystalline structure when deposited by ALD or CVD. On the other hand, nitrides and carbides (WNC, WN, WC, TiN, TaN, TaCN, TaC) may be nanocrystalline and embedded in an amorphous matrix.

The barrier layer 102 may be constructed as a composite multi-layer structure to effectively maximize the diffusion shield and adhesion characteristics of the barrier layer 102. For example, the barrier layer 102 may comprise a first film 102A and a second film 102B, as shown in FIGS. 1A and 1B. The first film 102A or diffusion shield film may include materials that form a better diffusion shield than the materials forming the second film 102B. Similarly, the second film 102B or adhesion film may include materials providing better adhesion to the subsequently deposited first conductive film 104 (which, as noted above, will tend to have high carbon content and therefore poorer adhesion to underlying materials) than the materials forming the first film 102A. In this respect, WNC, WN, WC, TiN or TaN, or a combination thereof, can be used to form the first film 102A; and Ru, Co, CoWP or Ni, or a combination thereof, can be used to form the second film 102B. Because of the scale involved in 3-D integration, MOCVD films can actually delaminate from conventional barrier materials when deposited directly over a barrier layer. Accordingly, use of a separate adhesion film, such as Ru, is particularly advantageous in adhesion with MOCVD seed layers. The ALD process may be performed using an ALD reactor commercially available from ASM International.

According to this embodiment, a first conductive layer 104 is then formed over the barrier layer 102, preferably using a MOCVD process, which partially fills the via 100, as shown in FIG. 1A. The first conductive layer 104 is a continuous layer having a substantially uniform thickness and conformally coating the barrier layer 102. Although the continuous layer may be grown to any predetermined thickness, the thickness range for the first conductive layer 104 is preferably about 50-700 nm, and more preferably about 300-500 nm. With these thickness ranges, the first conductive layer 104 may be viewed as a seed layer, preferably formed using a MOCVD process. Continuity and the uniformity of the first conductive layer 104 make it a defect-free base for the subsequent copper filling process. As used herein, a continuous layer refers to a layer with no holes or very thin regions relative to other portions of the layer. As mentioned above in the background section, such holes or weak layers cause defects, such as voids in the subsequently electrodeposited layer.

According to an embodiment, the MOCVD process may be continued to fully fill the via 100. In this embodiment, the first conductive layer 104 is formed of copper and deposited from a copper precursor. An exemplary MOCVD copper precursor may be CupraSelect®, which is commercially available from Air Products Inc. A catalyst selected from the group of elements named halogens, preferably iodine (I), may be added to the MOCVD precursor to promote bottom-up growth of the first conductive layer 104, which leads to higher growth rate and more efficient use of the precursor. Although iodine is the preferred catalyst, bromine (Br), or both I and Br, may also be used as a catalyst for this process. Examples of use of catalysts in gas phase deposition processes can be found in U.S. Pat. Nos. 6,623,799 and 6,720,262, the disclosures of which are hereby incorporated herein by reference for the purposes of teaching catalytic CVD of copper. Elemental I and Br can be supplied into the deposition chamber by sublimation. Typically, a precursor for I may be formulated as RI, where R represents hydrogen alkylcarbonyl, carboxy; or a substituted alkyl group with fluorines; or chlorines substituted for hydrogens. More specifically, a precursor may be iodomethane, trifluoroiodomethane, diiodomethane, 2-idopropane, and 2-methly-2-iodopropane, or bromotrimethylsilane, brometane, 2-bromopropane, 2-methyl-2-bromopropane.

Furthermore, prior to performing an ECD process, the same catalyst may be applied a second time to the first conductive layer 104 to enhance wetting of the surface of the first conductive layer 104 by the ECD plating solution and to promote bottom-up growth of the layer deposited by the ECD process. In the second application, the catalyst may be applied onto the already formed MOCVD copper layer. The MOCVD process may be performed using an MOCVD reactor (e.g., Dragon™) commercially available from ASM International.

As shown in FIG. 1B, after the first conductive layer 104 is deposited, a second conductive layer 112 is deposited, preferably using an electrochemical deposition process. In the illustrated process, the first conductive layer serves as a seed layer for ECD. As discussed above, the MOCVD first conductive layer is a conformal, defect-free layer. The conformality of the layer allows for more uniform application of current during ECD (or ECMD) of the second conductive layer 112. The skilled artisan will appreciate that a more uniform and conformal MOCVD layer allows for application of higher current density during a subsequent ECD process, thereby speeding deposition. Faster deposition is important for 3-D integration because of the depth of the vias and volume of copper needed to fill them. The current density used during ECD of the second conductive layer 112 is preferably in a range of about 5-20 mamp/cm², and more preferably about 8-12 mamp/cm². It will be understood that the higher the current density, the faster the deposition process. The skilled artisan will appreciate that the speed of the process also depends on the electrolyte chemistry, the dimensions of the via, the current density, etc.

The second conductive layer 112 comprises copper in the illustrated embodiment. The second conductive layer 112 fills the remaining space left in the via 100 and forms an excess layer 114 on the substrate 106. The electrochemical deposition process can be a standard electrochemical deposition (ECD) (leaving a non-uniform overburden 114) or a planar deposition process, such as electrochemical mechanical deposition (ECMD) (leaving a planar layer 116). The copper for the second conductive layer is deposited from a plating solution while a potential difference is applied between the first conductive layer 104 and a system anode electrode of a deposition system. In an embodiment, during the plating process, plating current is applied through surface electrical contacts (not shown) placed on the first conductive layer 104 uniformly coating the wafer surface and the interior of the deep vias (e.g., via 100).

Since the first conductive layer 104 is continuous and has a substantially uniform thickness, a sufficiently high plating current, as discussed above, is preferably driven down the deep via 100 during the process, resulting in forming the second conductive layer 112 without defects. The plating electrolyte may include bottom-up growth promoting additives, such as accelerators and suppressors. If the deposition process is a planar deposition process (e.g., ECMD), a planar excess layer 116 may form on the substrate, shown in dotted lines in FIG. 1B. ECMD is a planar deposition process during which a pad is applied on the surface of the wafer including features to promote deposition into the features while inhibiting deposition on the surface of the wafer, thereby forming a planar layer on the wafer surface. Having a thin planar layer on the wafer surface advantageously reduces subsequent planarization time and cost.

After completing electrodeposition of the second conductive layer 112, as shown in FIG. 1C, a planarization process is preferably applied to remove the copper on the surface of the substrate 106. As illustrated, surface portions of the barrier layer 102 can also be removed. The planarization process results in a conductive 3-D structure 120 or conductive plug, which is partially formed by the first conductive layer 104 and the second conductive layer 112 (see FIG. 1B) and is securely attached to the interior of the via 100 through the barrier layer 102. The planarization process electrically isolates the 3-D structure 120 in the deep via 100 from other neighboring devices and other 3-D structures of the wafer. A planarization process, such as chemical mechanical polishing (CMP) or electrochemical mechanical polishing (ECMP), may be used to planarize the substrate 106.

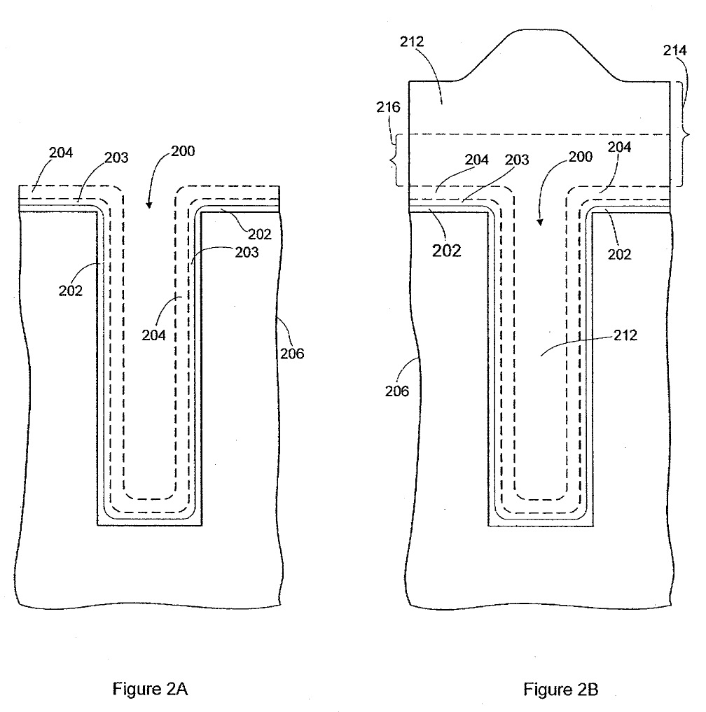

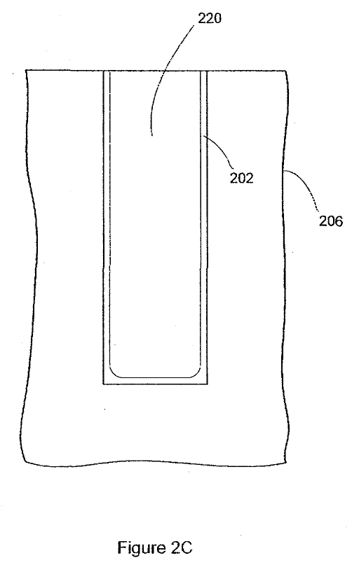

FIGS. 2A-2C show a second embodiment for forming a copper 3-D structure. As shown in FIG. 2A, an exemplary via 200 is coated with a barrier layer 202, a seed layer 203 and a first conductive layer 204. The exemplary via 200 is formed in a substrate 206, which may be a portion of a semiconductor wafer (e.g., silicon wafer) or a dielectric layer.

In this embodiment, the barrier layer 202 and the seed layer 203 may be formed of conventional copper electroplating liner materials, which are preferably formed using conventional PVD processes, or other processes. For example, the barrier layer 202 may be formed of Ta, TaN or both Ta/TaN (having a thickness of approximately 50-200 Å) and the seed layer 203 may be a copper seed layer (having a thickness of approximately 50-200 Å). In certain embodiments, the barrier layer 202 may be deposited onto a dielectric layer, such as SiO₂ (not shown).

The first conductive layer 204 is formed over the seed layer 203 using a gas phase deposition process, preferably a MOCVD process, which partially fills the via 200, as shown in FIG. 2A. Application of the MOCVD process is described in detail above. The first conductive layer 204 is preferably a continuous layer with substantially uniform thickness and conformally coats the seed layer 203 and underlying barrier layer 202. Although the first conductive layer 204 may be grown to any predetermined thickness, the thickness range for the first conductive layer 204 is preferably about 50-700 nm, and more preferably about 300-500 nm. The substantial continuity and uniformity of the first conductive layer 204 make it a defect free base for the subsequent copper filling process. As mentioned above in the background section, openings or weak regions in the seed layer cause defects, such as voids in the subsequently deposited copper layer. The first conductive layer 204 preferably mends any possible openings or discontinuities in the copper seed layer 203. As mentioned above, alternatively, the MOCVD process may be continued to fully fill the via 200 as well. A catalyst may be added to the MOCVD precursor to promote bottom-up growth of the first conductive layer 204, which leads to a higher growth rate and more efficient use of the precursor. Furthermore, prior to a subsequent ECD process, the same catalyst may be applied a second time to the first conductive layer 204 to enhance wetting of the surface by the ECD plating solution and to promote bottom up-growth of the depositing layer.

As shown in FIG. 2B, after the first conductive layer 204 is deposited, a second conductive layer 212 is deposited, preferably using an electrochemical deposition process. In the illustrated embodiment, the first conductive layer serves as an electroplating (ECD) seed layer. The second layer 212 comprises copper in this embodiment. The second conductive layer 212 fills the remaining space left within the via 200 and forms an excess layer 214 on the substrate 206, as illustrated in FIG. 2B. The electrochemical deposition process can be a standard electrochemical deposition (ECD) (leaving a non-uniform overburden 214) or a planar deposition process, such as electrochemical mechanical deposition (ECMD) (leaving a planar layer 216). The electrochemical deposition process is performed as described in the above embodiment. If the deposition process is a planar deposition process, a planar layer excess layer 216 may form on the substrate, as shown in dotted lines in FIG. 2B.

After completing the electrodeposition step, as shown in FIG. 2C, a planarization step (e.g., CMP or ECMP) is applied to remove the copper on the surface of the substrate 206, along with surface portions of the barrier layer 202. The planarization process reveals a conductive 3-D structure 220, which is partially formed by the first conductive layer 204 and the second conductive layer 212 (FIG. 2B) and is securely attached to the interior of the via 200 through the barrier layer 202. The planarization process electrically isolates the conductive 3-D structure 220 in the deep via 200 from other neighboring devices or other 3-D structures of the wafer. As discussed above, CMP or ECMP may be used to planarize the substrate 206.

Thereafter, processing is conducted to complete the 3-D integration (e.g., complete wafer metallization to connect integrated circuit components to the filled via 200; attach to handle wafer; grind backside of wafer to expose the bottom of the copper filling the via 200; mount chip on wafer to interconnect with other chips or wafers through the backside, etc.).

Accordingly, the embodiments described herein provide conformal barrier layers with substantially uniform thickness within deep, high aspect ratio vias with minimal barrier overburden on the surface of the wafer (field). The ALD deposited barrier layer is a good adhesion layer for the MOCVD deposited copper seed layer. The MOCVD deposited copper seed layer significantly improves copper coverage along the side walls and the bottom of the deep via, as compared to the PVD process of the prior art. The MOCVD deposited copper seed layer allows proper copper fill in the deep via without defects, such as seam formation and voids, and also allows for the use of higher current density (and uniform application of current density) for the subsequent electrochemical plating process, resulting in faster filling of the deep via without defects. Inclusion of a catalyst in the MOCVD process and/or at the end of the MOCVD process improves the wetting capabilities of the plating electrolyte during the subsequent electrochemical plating.

Although various preferred embodiments have been described in detail above, those skilled in the art will readily appreciate that many modifications of the exemplary embodiment are possible without materially departing from the novel teachings and advantages of the embodiments described herein.

What is claimed is:

1. A method of filling a deep feature formed in a surface of a wafer with a conductor, comprising:
forming a conductive film coating the deep feature and extending over the surface of the wafer, the deep feature having a depth of at least about 10 microns;
depositing a first layer over the conductive film using a gas phase deposition process, the first layer comprising the conductor and partially filling the deep feature; and
using an electrochemical deposition process to form a second layer over the first layer, the second layer comprising the conductor and completely filling the deep feature.

2. The method of claim 1, wherein the first layer is a conformal layer.

3. The method of claim 1, wherein the first layer has a substantially uniform thickness.

4. The method of claim 1, wherein forming the conductive layer is performed using an ALD process.

5. The method of claim 4, wherein the conductive layer has a thickness in the range of 1 to 10 nanometers.

6. The method of claim 4, wherein the conductive layer is a barrier layer.

7. The method of claim 6, wherein the barrier layer comprises at least one diffusion shield film and at least one adhesion film.

8. The method of claim 7, wherein the diffusion shield film comprises a material selected from the group consisting of WNC, WN, WC, Ti, Ta, TaC, TaCN, TiN and TaN.

9. The method of claim 7, wherein the adhesion film comprises a material selected from the group consisting of Ru, Co, CoWP and Ni.

10. The method of claim 6, wherein the barrier layer comprises a material selected from the group consisting of Ru, WNC, WN, WC, TiN, TaN, TaC, TaCN, Co, CoWP and Ni.

11. The method of claim 1, wherein the first layer has thickness in the range of 50 to 700 nm.

12. The method of claim 1, wherein the conductor is copper.

13. The method of claim 1, wherein the conductive layer comprises a barrier layer and a seed layer.

14. The method of claim 13, wherein the conductor is copper.

15. The method of claim 14, wherein the barrier layer comprises a material selected from the group consisting of Ta, Ti, TaN and TiN.

16. The method of claim 14, wherein the seed layer is a copper seed layer.

17. The method of claim 1, wherein the gas phase deposition process is MOCVD.

18. The method of claim 1, wherein the electrochemical deposition is ECD.

19. The method of claim 1, wherein the electrochemical deposition is ECMD.

20. The method of claim 1, further comprising including a catalyst during the gas phase deposition process.

21. The method of claim 20, further comprising treating a surface of the first layer with the catalyst before forming the second layer over the first layer.

22. A method of filling 3-D integration features formed in an upper surface of a wafer with a conductor, comprising:
forming a barrier layer coating interior surfaces of the features and extending over the upper surface of the wafer;
forming a seed layer over the barrier layer;
depositing a first layer over the seed layer using a gas phase deposition process, the first layer comprising the conductor and partially filling the features and extending over the upper surface of the wafer; and
using an electrochemical deposition process to form a second layer over the first layer, the second layer comprising the conductor and completely filling the features.

23. The method of claim 22, further comprising placing electrical contacts on the surface of the first layer prior to using the electrochemical deposition process.

24. The method of claim 23, further comprising applying a potential difference between the first layer and an electrode during the electrochemical deposition process.

25. The method of claim 22, wherein the first layer is a continuous layer.

26. The method of claim 22, wherein the conductor is copper.

27. The method of claim 22, wherein the barrier layer comprises a material selected from the group consisting of Ti, Ta, TaN, TiN, TaC, TaCN, WCN and WN.

28. The method of claim 22, wherein the seed layer is a copper seed layer.

29. The method of claim 22, wherein the gas phase deposition process is MOCVD.

30. The method of claim 22, wherein the electrochemical deposition process is ECD.

31. The method of claim 22, wherein the electrochemical deposition process is ECMD.

32. The method of claim 22, further comprising including a catalyst during the gas phase deposition process.

33. The method of claim 32, further comprising treating a surface of the first layer with the catalyst before forming the second layer over the first layer.

34. The method of claim 22, wherein the features have a depth of at least about 20 microns.

35. A method of filling a 3-D integration feature formed in an upper surface of a wafer with a conductor, comprising:
forming a conductive film coating the feature and extending over the upper surface of the wafer;
depositing a first conductor layer over the conductive film using a gas phase deposition process to at least partially fill the feature;
forming a second conductor layer over the first conductor layer to completely fill the feature; and
treating the first conductor layer with a catalyst before forming the second conductor layer.

36. The method of claim 35, wherein the catalyst is iodine.

37. The method of claim 35, wherein the catalyst is bromine.

38. The method of claim 35, wherein the feature has a depth of at least about 10 microns.

39. The method of claim 35, wherein the second conductor layer is formed by an electrochemical deposition process.

40. The method of claim 35, wherein the second conductor layer is formed by MOCVD.
